(19) United States
(12) Patent Application Publication
(10) Pub. No.: US 2025/0240007 A1
(43) Pub. Date: Jul. 24, 2025

(54) SHORT-CIRCUIT PROTECTION DEVICE FOR SWITCH

(71) Applicant: IUCF-HYU (INDUSTRY-UNIVERSITY COOPERATION FOUNDATION HANYANG UNIVERSITY), Seoul (KR)

(72) Inventors: Rae Young KIM, Seoul (KR); Meng Yao BAI, Bucheo-si, Gueonggi-do (KR); Sung Soo MIN, Changwon-si, Gyeongsangnam-do (KR)

(73) Assignee: IUCF-HYU (INDUSTRY-UNIVERSITY COOPERATION FOUNDATION HANYANG UNIVERSITY), Seoul (KR)

(21) Appl. No.: 18/702,092

(22) PCT Filed: Oct. 18, 2022
(86) PCT No.: PCT/KR2022/015864

§ 371 Date: Apr. 17, 2024

(30) Foreign Application Priority Data
Oct. 18, 2021 (KR) 10-2021-0138623
Oct. 11, 2022 (KR) 10-2022-0130001

(51) Int. Cl. H03K 17/082; G01R 19/165; G01R 31/52

(52) U.S. Cl. CPC H03K 17/0822; G01R 19/16519; G01R 19/16523; G01R 31/52

(57) ABSTRACT

Disclosed is a device for detecting and protecting a short circuit of a switch. A short-circuit protection device according to an embodiment of the present invention includes a voltage measurement unit configured to measure an output voltage of a switch and output the output voltage as a measured voltage, a comparison unit configured to compare the measured voltage with a specified reference voltage, and a connection unit that is connected between the voltage measurement unit and the comparison unit and in case that the switch is turned off, the connection unit is configured to connect an output terminal of the voltage measurement unit to a first ground.

### TECHNICAL FIELD

The present invention relates to a short-circuit protection device for a switch, and more particularly, to a short-circuit protection device for a switch that detects a short circuit in the switch and protects the switch.

### BACKGROUND ART

Power devices are semiconductor devices that convert or control power, and rectifier diodes, power transistors, triacs, etc. are used in various fields such as industry, information, communication, transportation, power, and home. Representative power devices include metal oxide semiconductor field effect transistors (MOSFETs), insulated gate bipolar transistors (IGBTs), bipolar junction transistors (BJTs), power integrated circuits (ICs), and GaN HEMTs, and among these, GaN HEMTs, which enable high-speed switching and have low driving circuit losses, are attracting particular attention.

In order for MOSFETs, GaN HEMTs, etc. to be applied to various applications, device stability needs to be ensured. In particular, if a short circuit occurs in a switch such as MOSFETs or GaN HEMTs, the switch such as MOSFETs or GaN HEMTs may break down within hundreds of nanoseconds, so a device that can quickly determine whether a switch is short-circuited is needed.

The matters described in the technical section forming the background of the present invention are for understanding the background of the present invention, and cannot be assumed to be prior art already known to one of ordinary skill in the art.

### DESCRIPTION OF EMBODIMENTS

### Technical Problem

The present invention provides a short-circuit protection device for a switch capable of preventing malfunctions by securing a relatively large noise margin despite using a desaturation-based detection method that is easy to implement from among methods of detecting short circuits in switches, thereby increasing resistance to voltage fluctuation noise (i.e., dv/dt noise) caused by high-speed switching.

Furthermore, the present invention provides a short-circuit protection device for a switch capable of quickly detecting overcurrent and turning off the switch before the switch breaks down due to the overcurrent to protect the switch.

### Solution to Problem

According to one aspect of the present invention, provided is a device for detecting and protecting a short circuit of a switch including: a voltage measurement unit configured to measure an output voltage of the switch and output the output voltage as a measured voltage; a comparison unit configured to compare the measured voltage with a specified reference voltage; and a connection unit that is connected between the voltage measurement unit and the comparison unit, and in case that the switch is turned off, the connection unit is configured to connect an output terminal of the voltage measurement unit to a first ground.

According to an embodiment, the voltage measurement unit may include: a diode in which a cathode is connected to an output terminal of the switch; a first resistor in which one end is connected to an anode of the diode; a second resistor in which one end receives an external power voltage, and the other end is connected to the other end of the first resistor; and a capacitor connecting the other end of the first resistor to a second ground, and may output a voltage applied to both ends of the capacitor as the measured voltage.

According to an embodiment, the connection unit may include: a MOSFET in which a drain is connected to an output terminal of the voltage measurement unit and a source is connected to the first ground; and an inverter that receives a control signal input to the switch, inverts the received control signal, and transmits the inverted control signal to a gate of the MOSFET.

According to an embodiment, in case that the switch is turned off, the MOSFET may be turned on, and the output terminal of the voltage measurement unit may be connected to the first ground, the capacitor is discharged.

According to an embodiment, the comparison unit may include: a third resistor that receives an external power voltage at one end; a fourth resistor connecting the other end of the third resistor to a third ground; and a comparator in which a first input terminal (+) is connected to the output terminal of the voltage measurement unit to receive the measured voltage, and a second input terminal (−) is connected to the other end of the third resistor and receives a voltage applied to both ends of the fourth resistor as a reference voltage, wherein, when the measured voltage is equal to or greater than the reference voltage, the comparator may output a pre-determined error signal.

According to an embodiment, the device for detecting and protecting a short circuit of a switch may further include: a control unit configured to turn off the power switch according to the error signal from the comparison unit, wherein the switch is a power switch, and the measured voltage is a drain-source voltage of the power switch.

According to an embodiment, an external power voltage, Vext, supplied to one end of the second resistor and one end of the third resistor may be greater than a gate turn-on voltage, Vg on, provided to a gate to turn on the power switch.

### ADVANTAGEOUS EFFECTS OF DISCLOSURE

A short-circuit protection device for a switch according to an embodiment of the present invention may prevent malfunctions by securing a relatively large noise margin despite using a desaturation-based detection method that is easy to implement from among methods of detecting short circuits in switches, thereby increasing resistance to voltage fluctuation noise (i.e., dv/dt noise) caused by high-speed switching.

Furthermore, a short-circuit protection device for a switch according to an embodiment of the present invention may quickly detect overcurrent and turn off the switch before the switch breaks down due to the overcurrent to protect the switch.

### BRIEF DESCRIPTION OF DRAWINGS

FIG. 1 is an exemplary view of a short-circuit protection device for a power switch according to the prior art.

FIG. 2 is a view illustrating a short-circuit protection device according to an embodiment of the present invention.

FIG. 3 is an exemplary view of a connection unit according to an embodiment of the present invention.

FIG. 4 is a view illustrating results of simulating noise margins of a short-circuit protection device according to the prior art and a short-circuit protection device according to an embodiment of the present invention.

FIGS. 5 and 6 are views illustrating results of comparing overcurrent detection times of a short-circuit protection device according to the prior art and a short-circuit protection device according to an embodiment of the present invention, by simulating them under HSF conditions in an arm short circuit.

### MODE OF DISCLOSURE

Since the present invention may have diverse modified embodiments, preferred embodiments are illustrated in the drawings and are described in the detailed description. However, this is not intended to limit the present invention to particular modes of practice, and it is to be appreciated that all changes, equivalents, and substitutes that do not depart from the spirit and technical scope of the present invention are encompassed in the present invention.

In the description of the present invention, certain detailed explanations of the related art are omitted when it is deemed that they may unnecessarily obscure the essence of the present invention. In addition, numeral figures (e.g., 1, 2, and the like) used during describing the specification are just identification symbols for distinguishing one element from another element.

Further, in the specification, if it is described that one element is “connected” or “accesses” the other element, it is understood that the one element may be directly connected to or may directly access the other element but unless explicitly described to the contrary, another element may be “connected” or “access” between the elements.

In addition, it will be understood that when a unit is referred to as “comprising” another element, it may not exclude the other element but may further include the other element unless specifically oppositely indicated. In addition, terms such as “ . . . unit”, “ . . . module”, or the like refer to units that perform at least one function or operation, and the units may be implemented as one or more hardware or software or as a combination of hardware and software.

Reference will now be made in detail to embodiments, examples of which are illustrated in the accompanying drawings.

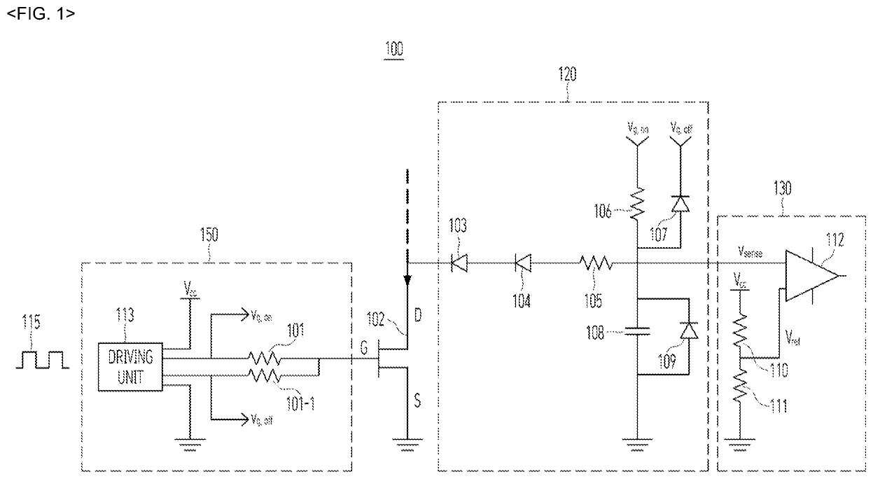

FIG. 1 is an exemplary view of a short-circuit protection device for a power switch according to the prior art.

Referring to FIG. 1, a short-circuit protection circuit 100 for a power switch 102 according to the prior art may measure a drain-source voltage of the power switch 102 in a voltage measurement unit 120 and output the drain-source voltage as a measured voltage Vsense. In addition, a comparison unit 130 may compare the measured voltage Vsense with a specified reference voltage Vref, and when the measured voltage Vsense is greater than or equal to the reference voltage Vref, may determine that the power switch 102 is short-circuited.

When the power switch 102 is normally turned on in a steady-state, the measured voltage Vsense may be calculated using Equation (1) below.

$${V}_{sense} = {V}_{g , on} - \frac{R 1}{R 1 + R 2} ( {V}_{g , on} - {V}_{ds} - {V}_{D 1 - F} - {V}_{D 2 - F} ) \qquad ( 1 )$$

Where Vsense is a measured voltage, Vg, on is a gate turn-on voltage supplied to a gate to turn on the power switch 102, R1 is a resistance value of a first resistor 105, R2 is a resistance value of a second resistor 106, Vds is a drain-source voltage of the power switch 102, and VD1_F and VD2_F are forward voltage drop values of a first diode 103 and a second diode 104.

Here, when a resistance value R1 of the first resistor 105 is much greater than a resistance value R2 of the second resistor 106, the measured voltage Vsense of Equation (1) may be summarized as Equation (2) below.

$${V}_{sense} \approx {V}_{ds} + {V}_{D 1 - F} + {V}_{D 2 - F} \qquad ( 2 )$$

The reference voltage Vref may be set to a pre-determined value by setting resistance values of a third resistor 110 and a fourth resistor 111.

If a maximum value of the reference voltage Vref is considered, the reference voltage Vref may be a maximum charging voltage charged in a capacitor 108 when overcurrent flows through the power switch 102. In this case, the maximum charging voltage charged to the capacitor 108 may be the gate turn-on voltage Vg,on supplied to a gate to turn on the power switch 102.

Therefore, in the short-circuit protection device 100 for the power switch 102 according to the prior art, a difference between the reference voltage Vref and the measured voltage Vsense, that is, a noise margin, may be summarized as Equation (3) below.

$${V}_{margin} = {V}_{ref} - {V}_{sense} \approx {V}_{g , on} - {V}_{ds} - {V}_{D 1 - F} - {V}_{D 2 - F} \qquad ( 3 )$$

Where Vmargin is a difference (hereinafter referred to as ‘noise margin’) between the reference voltage Vref and the measured voltage Vsense, Vref is a reference voltage, Vsense is a measured voltage, Vg,on is a gate turn-on voltage supplied to a gate to turn on the power switch 102, Vds is a drain-source voltage of the power switch 102, and VD1_F and VD2_F are forward voltage drop values of the first diode 103 and the second diode 104.

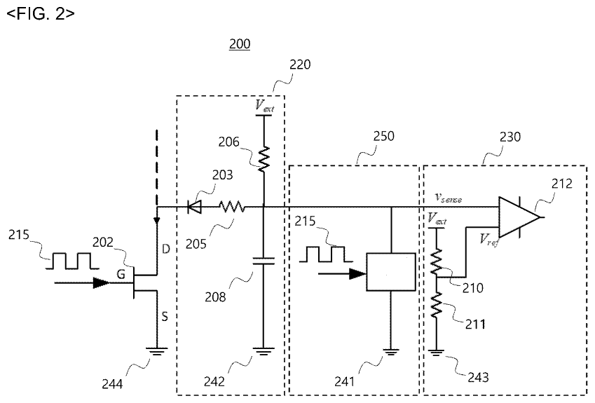

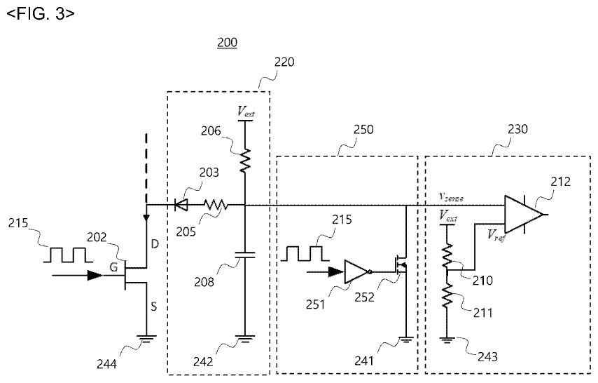

Hereinafter, a short-circuit protection device for a switch according to an embodiment of the present invention will be described with reference to FIGS. 2 and 3, and then compared with the short-circuit protection device 100 for the power switch according to the prior art.

FIG. 2 is a view illustrating a short-circuit protection device for a switch (hereinafter referred to as ‘short-circuit protection device’) according to an embodiment of the present invention, and FIG. 3 is an exemplary view of a connection unit according to an embodiment of the present invention.

Referring to FIG. 2, a short-circuit protection device 200 according to an embodiment of the present invention may include a voltage measurement unit 220, a comparison unit 230, a connection unit 250, and a control unit (not shown).

Hereinafter, in explaining the present invention, a switch 202 is illustrated as a power switch using a MOSFET, but a switch to which the present invention may be applied is not limited thereto. For example, the switch may be a variety of switches using a metal oxide semiconductor field effect transistor (MOSFET), an insulated gate bipolar transistor (IGBT), a bipolar junction transistor (BJT), a power integrated circuit (IC), GaN HEMTs, etc.

In addition, the switch 202 may be turned on or off depending on an input control signal 215.

The short-circuit protection device 200 according to an embodiment of the present invention may include the voltage measurement unit 220 that measures an output voltage of the switch 202 and outputs the output voltage as the measured voltage Vsense.

Referring to FIG. 2, the voltage measurement unit 220 may include a diode 203 in which a cathode is connected to an output terminal of the switch 202, a first resistor 205 in which one end is connected to an anode of the diode 203, a second resistor 206 in which one end receives an external power voltage Vext and the other end is connected to the other end of the first resistor 205, and a capacitor 208 connecting the other end of the first resistor 205 to a second ground 242.

Here, the external power voltage Vext may be a value greater than the gate turn-on voltage Vg,on provided to a gate of the switch 202 to turn on the switch 202. For example, the external power voltage Vext may be +10 V, and the gate turn-on voltage Vg,on may be +6 V.

The voltage measurement unit 220 may output a voltage applied to both ends of the capacitor 208 as the measured voltage Vsense.

For example, when the switch 202 is normally turned on in a steady-state, the measured voltage Vsense may be calculated using Equation (4) below.

$${V}_{sense} = {V}_{ext} - \frac{R 1}{R 1 + R 2} ( {V}_{ext} - {V}_{ds} - {V}_{D 1 - F} ) \qquad ( 4 )$$

Where Vsense is a measured voltage, Vext is an external power voltage received from a separate external power supply, R1 is a resistance value of the first resistor 105, R2 is a resistance value of the second resistor 106, Vds is a drain-source voltage of the power switch 102, and VD1_F is a forward voltage drop value of the first diode 203.

Here, when the resistance value R1 of the first resistor 205 is much greater than the resistance value R2 of the second resistor 206, the measured voltage Vsense of Equation (4) may be summarized as Equation (5) below.

$${V}_{sense} \approx {V}_{ds} + {V}_{D 1 - F} \qquad ( 5 )$$

The short-circuit protection device 200 according to an embodiment of the present invention may include the comparison unit 230 that compares the measured voltage Vsense with the reference voltage Vref.

Here, a value output by the comparison unit 230 when the measured voltage Vsense is less than the reference voltage Vref and a value output by the comparison unit 230 when the measured voltage Vsense is equal to or greater than the reference voltage Vref may be designated differently.

For example, when the measured voltage Vsense is equal to or greater than the reference voltage Vref, the comparison unit 230 may output a pre-determined error signal.

Referring to FIG. 2, the comparison unit 230 may include a third resistor 210 that receives the external power voltage Vext at one end, a fourth resistor 211 connecting the other end of the third resistor 210 to a third ground 243, and a comparator 212 in which a first input terminal (+) is connected to an output terminal of the voltage measurement unit 220 to receive the measured voltage Vsense, and a second input terminal (−) is connected to the other end of the third resistor 210 and receives a voltage applied to both ends of the fourth resistor 211 as the reference voltage Vref.

In FIG. 2, as an example of the comparison unit 230, resistance values of the third resistor 210 and the fourth resistor 211 are set, and the reference voltage Vref is set to a pre-determined value. However, this is only an example, and it will be apparent to one of ordinary skill in the art that the reference voltage Vref may be set in various ways known at the time of filing the present invention.

Here, considering a maximum value of the reference voltage, Vref, the capacitor 208 may be charged by a maximum charging voltage when overcurrent flows through the power switch 202. In this case, the maximum charging voltage charged to the capacitor 208 may be the external power voltage Vext received from a separate external power supply and supplied to one end of the second resistor 206. Here, in the short-circuit protection device 200 according to an embodiment of the present invention, the external power voltage Vext is input to one end of the third resistor 210, and the resistance values of the third resistor 210 and the fourth resistor 211 are set, so that the reference voltage Vref may be set to various values depending on the environment to which the present invention is applied.

In the short-circuit protection device 200 of the switch 202 according to an embodiment of the present invention, a margin between the reference voltage Vref and the measured voltage Vsense may be summarized as Equation (6) below.

$${V}_{margin} = {V}_{ref} - {V}_{sense} \approx {V}_{ext} - {V}_{ds} - {V}_{D 1 - F} \qquad ( 6 )$$

Where Vmargin is a difference (i.e., noise margin) between the reference voltage Vref and the measured voltage Vsense, Vref is a reference voltage, Vsense is a measured voltage, Vext is an external power voltage supplied to a separate external power supply, Vds is a drain-source voltage of the power switch 102, and VD1_F is a forward voltage drop value of the first diode 103.

The short-circuit protection device 200 according to an embodiment of the present invention may include a control unit (not shown) that turns on or off the switch 202 according to an output of the comparison unit 230.

Here, the control unit (not shown) may be implemented as a software module integrated into any one of the above-described configurations, or may be implemented as a separate hardware independent configuration, and may be provided in various ways depending on the environment to which the present invention is applied.

The short-circuit protection device 200 according to an embodiment of the present invention may include a connection unit 250 connected between the voltage measurement unit 220 and the comparison unit 230, turns on when the switch 202 is turned off, and connects the output terminal of the voltage measurement unit 220 to a first ground 241.

Referring to FIG. 3, the connection unit 250 according to an embodiment of the present invention may include a MOSFET 252 in which a drain is connected to the output terminal of the voltage measurement unit 220 and a source is connected to the first ground 241, and an inverter 251 that receives the same control signal 215 input to the switch 202, inverts the control signal 215, and transmits the control signal 215 to a gate of the MOSFET 252.

For example, when the switch 202 is turned off according to the input control signal 215, the same control signal 215 input to the switch 202 may be inverted in the inverter 251 and input to the gate of the MOSFET 252, and the MOSFET 252 may be turned on and electrically conducted. In this case, the output terminal of the voltage measurement unit 220 connected to a drain of the MOSFET 252 is connected to the first ground 241 to discharge the voltage charged in the capacitor 208, and as a result, the measured voltage Vsense may be 0 V.

Referring again to FIG. 1, in the short-circuit protection device 100 according to the prior art, even when the power switch 102 is turned off, the capacitor 108 is charged with the measured voltage Vsense. In this case, even though the power switch 202 is operating normally, if voltage fluctuation noise (i.e., dv/dt noise) due to high-speed switching occurs, the voltage fluctuation noise may be added to the measured voltage Vsense charged in the capacitor 108 and may momentarily become greater than the reference voltage Vref, causing the short-circuit protection device 100 to malfunction.

Referring again to FIG. 2, in the short-circuit protection device 200 according to an embodiment of the present invention, when the switch 202 is turned off, the capacitor 208 is connected to the first ground 241 and is discharged, so the measured voltage Vsense becomes 0 V. In this case, even if voltage fluctuation noise (i.e., dv/dt noise) occurs due to high-speed switching of the switch 202, it is very unlikely that its value alone will be greater than the reference voltage Vref. Therefore, the short-circuit protection device 200 according to an embodiment of the present invention has the advantage of having a very low possibility of malfunction.

In FIGS. 2 and 3, an embodiment in which the control signal 215 input to the switch 202 is equally input to the connection unit 250 and the inverter 251 included in the connection unit 250 inverts the control signal 215 has been described. However, the embodiment may be applied with various modifications depending on the environment to which the present invention is applied. For example, the control signal 215 input to the switch 202 may be inverted in another configuration, and the inverted control signal may be input to the connection unit 250. In this case, it will be apparent to one of ordinary skill in the art that the inverter 251 of the connection unit 250 can be omitted in light of the technical idea of the present invention.

In addition, in FIGS. 2 and 3, the first to fourth grounds 241, 242, 243, and 244 are separately illustrated, but it will be apparent to one of ordinary skill in the art that the first to fourth grounds 241, 242, 243, and 244 may be implemented in various ways, such as consisting of one ground, some of them as one, or all of them independently, depending on the environment to which the present invention is applied.

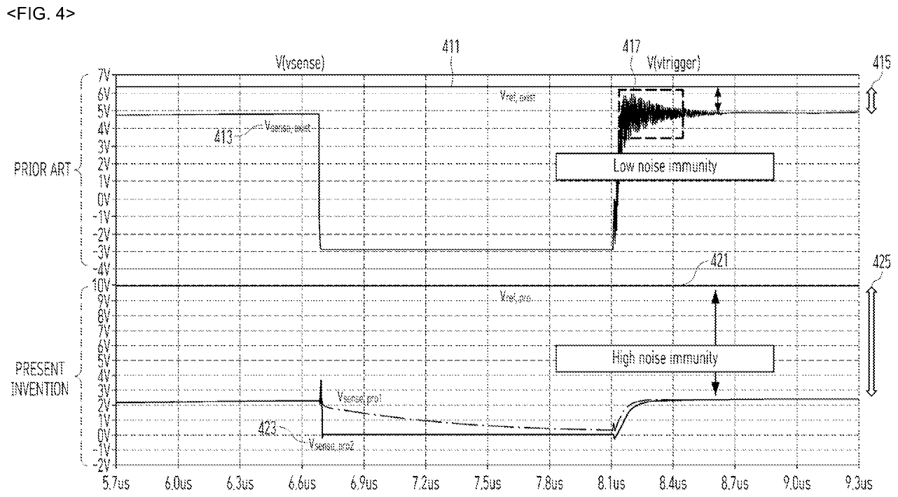

FIGS. 4 to 6 show results of simulating the short-circuit protection device 100 according to the prior art and the short-circuit protection device 200 according to an embodiment of the present invention using LTspice.

Hereinafter, with reference to FIGS. 4 to 6, a comparison will be made between the short-circuit protection device 100 according to the prior art and the short-circuit protection device 200 according to an embodiment of the present invention.

First, referring to FIGS. 1 and 2, depending on the control signals 115 and 215, the driving unit 113 (in FIG. 1) may provide the gate turn-on voltage Vg,on or a gate turn-off voltage Vg, off to gates of the switches 102 and 202. Here, the gate turn-on voltage Vg, on is a voltage supplied by the driving unit 113 (in FIG. 1) to the gates of the switches 102 and 202 to turn on the switches 102 and 202, and the gate turn-off voltage Vg, off is a voltage supplied by the driving unit 113 (in FIG. 1) to the gates of the switches 102 and 202 to turn off the switches 102 and 202.

In FIG. 2, the configuration (i.e., 150 in FIG. 1) in which a driving unit (not shown) provides the gate turn-on voltage Vg, on and the gate turn-off voltage Vg, off according to the control signal 215 is not shown, but it can be understood that the configuration is included in FIG. 2.

Hereinafter, in FIGS. 1 and 2, the switches 102 and 202 use GaN HEMTs (Gallium nitride high electron mobility transistors, e.g. GS66508T produced by GaN Systems Inc.) as an example, and are simulated accordingly by setting the gate turn-on voltage Vg,on to +6 V and the gate turn-off voltage Vg,on to −3 V. However, the switches 102 and 202 to which the present invention may be applied may include one or more of the various switches known at the time of filing the present invention, as described above. Accordingly, the gate turn-on voltage Vg,on and gate turn-off voltage Vg, off may also be set in various ways corresponding to the switch.

A general power voltage Vcc supplied to the driving unit 113 (in FIG. 1) is set to +6 V, the same as the gate turn-on voltage Vg,on, but this is only an example to facilitate understanding and explanation of the present invention. The general power voltage Vcc may be set to various values depending on the environment to which the present invention is applied.

Furthermore, in FIG. 2, according to an embodiment of the present invention, the external power voltage Vext supplied to one end of the second resistor 206 and one end of the third resistor 210 is set to +10 V, but this is also just an example to facilitate understanding and explanation of the present invention. The external power voltage Vext may be set to various values depending on the environment to which the present invention is applied.

The capacitors 108 and 208 are set to 240 pF as an example, and the MOSFET 252 (in FIG. 1) is set to DMN67D8LW produced by Diodes Incorporated as an example.

FIG. 4 is a view illustrating results of simulating noise margins of the short-circuit protection device 100 according to the prior art and the short-circuit protection device 200 according to an embodiment of the present invention.

As previously explained with reference to FIG. 1, when considering a maximum value, the reference voltage, Vref (referred to as ‘Vref.exit’ in the drawing), in the short-circuit protection device 100 according to the prior art may be +6 V as the gate turn-on voltage Vg,on. In this simulation, values of the third resistor 110 and the fourth resistor 111 are adjusted and set to +5 V (411) in advance.

In addition, as previously explained with reference to FIG. 2, in the short-circuit protection device 200, the external power voltage, Vext, is set to +10 V, and a reference voltage (referred to as ‘Vref.pro2’ in the drawing) of this simulation is set to about +10 V by adjusting resistance values of the third resistor 210 and the fourth resistor 210 in the short-circuit protection device 200.

Comparing Equation 3 (noise margin in the prior art) and Equation 6 (noise margin in an embodiment of the present invention) described above, it can be seen that a noise margin 425 of the short-circuit protection device 200 according to an embodiment of the present invention is relatively greater than a noise margin 415 of the short-circuit protection device 100 according to the prior art.

Thus, in the prior art for detecting a short circuit in the power switch 102, a desaturation-based detection method is easy to implement, but as voltage fluctuation noise (i.e., dv/dt noise) due to high-speed switching occurs and resulting triggering 417 (in FIG. 4) occurs, even though the power switch 102 is operating normally in an environment with the relatively small noise margin 415, there is a problem that a malfunction occurs when a measured voltage, Vsense.exit, 413 exceeds a reference voltage, Vref.exit, 411 and the switch is determined to be short-circuited.

However, according to an embodiment of the present invention, the short-circuit protection device 200 may prevent malfunctions by securing the relatively large noise margin 425 despite using the desaturation-based detection method that is easy to implement, thereby increasing resistance to voltage fluctuation noise (i.e., dv/dt noise) caused by high-speed switching.

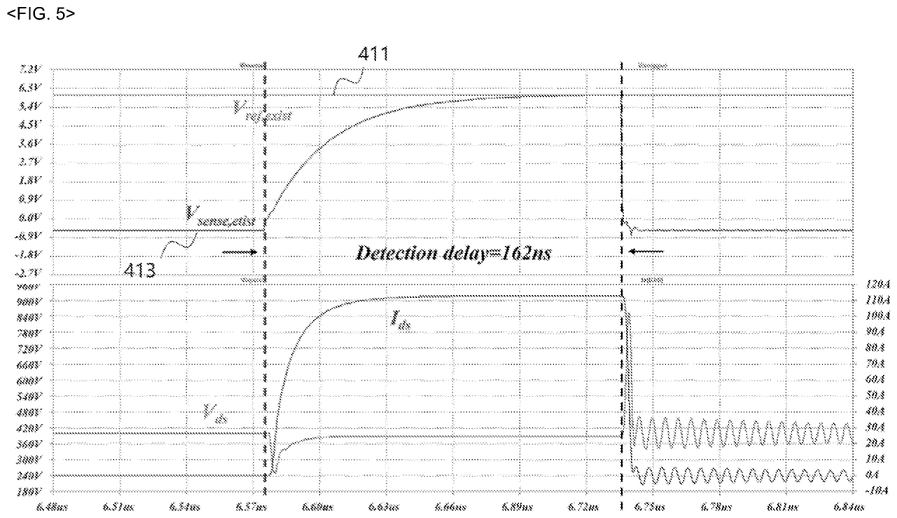

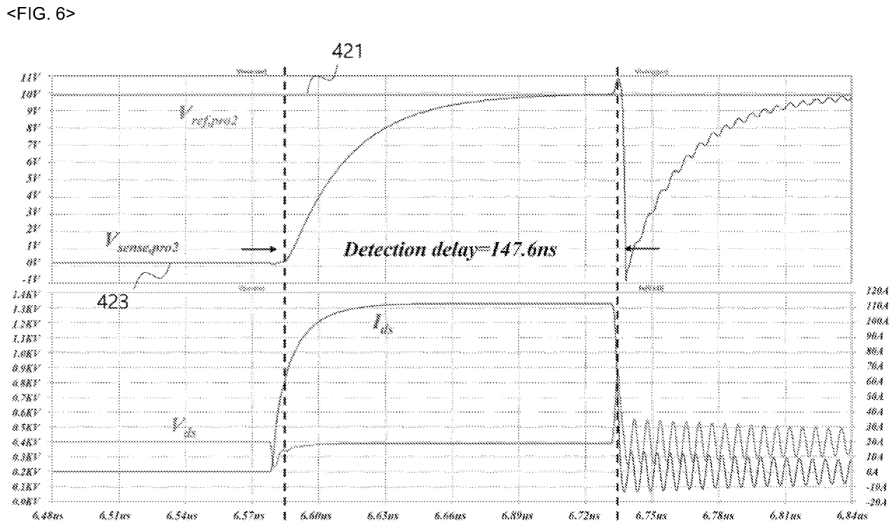

FIGS. 5 and 6 are results of comparing overcurrent detection times of the short-circuit protection device 100 according to the prior art and the short-circuit protection device 200 according to an embodiment of the present invention, by simulating them under HSF conditions in an arm short circuit.

The arm short circuit may be divided into hard switching fault (HSF) and fault under load (FUL). Because HSF and FUL are known information at the time of filing the present invention, detailed description thereof is omitted in this specification.

However, in the case of HSF, the capacitors 108 and 208 start charging at 0 V, while FUL charges at the measured voltage, Vsense. Therefore, considering an overcurrent detection time, the HSF conditions require longer time than FUL conditions, so this simulation is performed for the HSF conditions.

Referring to FIGS. 5 and 6, comparing times to detect overcurrent, the short-circuit protection device 100 according to the prior art takes 162 ns, while the short-circuit protection device 200 according to an embodiment of the present invention takes 147.6 ns, so it can be seen that the short-circuit protection device 200 according to an embodiment of the present invention may detect overcurrent more quickly.

Furthermore, it will be apparent to one of ordinary skill in the art in light of the technical idea of the present invention that in the FUL conditions, where it takes less time to detect overcurrent than in the HSF conditions, the short-circuit protection device 200 may detect overcurrent faster than 147.6 ns.

Therefore, because the short-circuit protection device 200 according to an embodiment of the present invention may increase the noise margin 425 to prevent malfunctions due to voltage fluctuation noise (dv/dt) caused by high-speed switching and may quickly detect overcurrent within 200 ns, so the short-circuit protection device 200 has the advantage of quickly protecting the switch 202 before the switch 202 breaks down.

While the embodiments of the present invention have been particularly shown and described, it will be understood by one of ordinary skill in the art that various changes in form and details may be made therein without departing from the spirit and scope of the disclosure as defined by the appended claims.

1. A device for detecting and protecting a short circuit of a switch, the device comprising:
a voltage measurement unit configured to measure an output voltage of the switch and output the output voltage as a measured voltage;
a comparison unit configured to compare the measured voltage with a specified reference voltage; and
a connection unit that is connected between the voltage measurement unit and the comparison unit, and
in case that the switch is turned off, the connection unit is configured to connect an output terminal of the voltage measurement unit to a first ground.

2. The device of claim 1, wherein the voltage measurement unit comprises:
a diode in which a cathode is connected to an output terminal of the switch;
a first resistor in which one end is connected to an anode of the diode;
a second resistor in which one end receives an external power voltage, and the other end is connected to the other end of the first resistor; and
a capacitor connecting the other end of the first resistor to a second ground, and
wherein the voltage measurement unit is configured to output a voltage applied to both ends of the capacitor as the measured voltage.

3. The device of claim 1, wherein the connection unit comprises:
a MOSFET in which a drain is connected to an output terminal of the voltage measurement unit and a source is connected to the first ground; and
an inverter that receives a control signal input to the switch, inverts the received control signal, and transmits the inverted control signal to a gate of the MOSFET.

4. The device of claim 3, wherein, in case that the switch is turned off, the MOSFET is turned on, and the output terminal of the voltage measurement unit is connected to the first ground, the capacitor is discharged.

5. The device of claim 1, wherein the comparison unit comprises:
a third resistor that receives an external power voltage at one end;
a fourth resistor connecting the other end of the third resistor to a third ground; and
a comparator in which a first input terminal (+) is connected to the output terminal of the voltage measurement unit to receive the measured voltage, and a second input terminal (−) is connected to the other end of the third resistor and receives a voltage applied to both ends of the fourth resistor as a reference voltage,
wherein, when the measured voltage is equal to or greater than the reference voltage, the comparator outputs a pre-determined error signal.

6. The device of claim 5, further comprising:
a control unit configured to turn off the power switch according to the error signal from the comparison unit,
wherein the switch is a power switch, and
the measured voltage is a drain-source voltage of the power switch.

7. The device of claim 5, wherein an external power voltage supplied to one end of the second resistor and one end of the third resistor is greater than a gate turn-on voltage provided to a gate to turn on the power switch.
